(19) United States
(12) Patent Application Publication
(10) Pub. No.: US 2023/0223962 A1
(43) Pub. Date: Jul. 13, 2023

(54) RF MULTIPLEXER OF 5G MMWAVE LOW-LOSS BROADBAND WIRELESS HYBRID TYPE USING WAVEGUIDE CAVITY KA-BAND

(71) Applicants: Jae Bok LEE, Hwaseong-si (KR); ERANGTEK, Hwaseong-si (KR)

(72) Inventors: Jae Bok LEE, Gyeonggi-do (KR); Young Nam JI, Anyang-si (KR)

(21) Appl. No.: 17/940,705

(22) Filed: Sep. 8, 2022

(30) Foreign Application Priority Data
Jan. 10, 2022 (KR) 10-2022-0003639

(51) Int. Cl. H04B 1/00; H01P 1/213

(52) U.S. Cl. CPC H04B 1/0057; H01P 1/2138

(57) ABSTRACT

Proposed is a radio frequency (RF) multiplexer of a 5G mmWave low-loss broadband wireless hybrid type using a waveguide cavity Ka-band in which outputs of a mobile communication band communication system using a plurality of satellite frequencies are combined, thereby reducing an insertion loss and increasing passive inter-modulation distortion (PIMD) performance, and signals at adjacent frequencies in a 5G mobile communication band are effectively filtered using a single mode or multiple modes, thereby reducing a size of a filter to reduce a weight thereof. The RF multiplexer of the 5G mmWave low-loss broadband wireless hybrid type using the waveguide cavity Ka-band includes bandpass filters which may receive signals in an RF frequency band to perform tuning and a coupler which combines outputs of at least two bandpass filters to match an antenna.

### CROSS-REFERENCE TO RELATED APPLICATION

This application claims priority to and the benefit of Korean Patent Application No. 2022-0003639, filed on Jan. 10, 2022, the disclosure of which is incorporated herein by reference in its entirety.

### BACKGROUND

### 1. Field of the Invention

The present invention relates to a radio frequency (RF) multiplexer of a 5G mmWave low-loss broadband wireless hybrid type using a waveguide cavity Ka-band, and more particularly, to mutually combining outputs of a mobile communication band communication system using a plurality of satellite frequencies. That is, the present invention relates to an RF multiplexer of a 5G mmWave low-loss broadband wireless hybrid type using a waveguide cavity Ka-band in which signals at adjacent frequencies in a 5G mobile communication band are effectively filtered, thereby reducing a size of a filter.

### 2. Discussion of Related Art

Technology in which 5G communication technology, which is the core strategic technology of the fourth industrial revolution, is integrated with a satellite network beyond a terrestrial network is being developed. In particular, since the COVID-19 pandemic, a data-based technology-oriented industrial ecosystem, in which the market is reorganized from price competitiveness to technological competitiveness due to the expansion of investment in a data-based global 5G market, has become more imminent.

Since Korea was the first in the world to commercialize 5G, in order to preoccupy 5G core technology and create an ecosystem thereof, global leading companies have also been investing much time and money to secure a technological competitive advantage for government, private companies, and public institutions.

Cooperation of the three mobile communication companies to co-build 5G in Korea as well as cooperation to share 5G between the mobile communication companies to reduce infrastructure costs in global markets of Japan, China, Germany, and the like are expected to begin in earnest. Separately, a multiplexer has been developed for common use of the three mobile communication companies.

As an example, Korean Patent Publication No. 10-2018-0064054 discloses a suspended structure including a floating printed circuit board (PCB) in which a broadband diplexer is implemented using a low pass filter and a high pass filter and which is capable of minimizing a tunneling effect, which is a main cause of contact nonlinear passive inter-modulation distortion (PIMD), to improve PIMD performance.

However, in this case, it is difficult to combine signals in adjacent frequency bands, and in particular, it is difficult to apply the suspended structure at a 5G satellite frequency of 28 GHz.

### RELATED ART DOCUMENTS

### Patent Documents

(Patent Document 1) Korean Patent Publication No. 10-2018-0064054 (published on Jun. 14, 2018)

### SUMMARY OF THE INVENTION

The present invention is directed to providing a radio frequency (RF) multiplexer of a 5G mmWave low-loss broadband wireless hybrid type using a waveguide cavity Ka-band in which outputs of a mobile communication band communication system using a plurality of satellite frequencies are combined, thereby reducing an insertion loss and increasing passive inter-modulation distortion (PIMD) performance.

The present invention is also directed to providing an RF multiplexer of a 5G mmWave low-loss broadband wireless hybrid type using a waveguide cavity Ka-band in which signals at adjacent frequencies in a 5G mobile communication band are effectively filtered using a single mode or multiple modes, thereby reducing a size of a filter to reduce a weight thereof.

According to an aspect of the present invention, there is provided an RF multiplexer of a 5G mmWave low-loss broadband wireless hybrid type using a waveguide cavity Ka-band, including band-pass filters which receive signals in an RF frequency band to perform tuning, and a coupler which combines outputs of at least two bandpass filters to match an antenna.

The RF frequency band may be a satellite frequency band and use a first band of 26.5 GHz to 27.3 GHz, a second band of 27.3 GHz to 28.1 GHz, and a third band of 28.1 GHz to 28.9 GHz.

The bandpass filter may be formed by consecutively coupling resonators in one mode or at least two different modes.

The mode may use a TE114 mode.

The mode may use a TE011 mode.

The coupler may combine the outputs of the at least two bandpass filters through a signal connection wall to couple the outputs to a common pole.

The signal connection wall may include a base configured to connect the bandpass filter and the coupler, and an upper extension portion positioned on an upper end of the base.

The tuning may be performed based on a result of performing machine learning using an artificial intelligence learning model based on an input/output value and a tuning depth of the RF multiplexer including the plurality of bandpass filters and one coupler.

The artificial intelligence learning model may include an input layer, a hidden layer, and an output layer, the input/output value and the tuning depth of the RF multiplexer may be input to the input layer, and tuning depth control may be performed through the output layer to satisfy a target characteristic.

The target characteristic may be at least one of an insertion loss for each frequency, a reflective loss, and isolation between inputs.

In the machine learning, a reward function of Monte-Carlo learning may be updated based on a condition that satisfies the target characteristic.

In the machine learning, for the tuning depth control for satisfying the target characteristic, temporal difference learning for updating a reward function immediately for each time step may be performed, and when the target characteristic is satisfied, Monte-Carlo learning for updating a reward function for all states may be performed based on the target characteristic.

### BRIEF DESCRIPTION OF THE DRAWINGS

FIG. 1 is a configuration diagram illustrating a radio frequency (RF) multiplexer of a 5G mmWave low-loss broadband wireless hybrid type using a waveguide cavity Ka-band according to one embodiment of the present invention.

FIG. 2 is a block diagram illustrating the RF multiplexer of FIG. 1 in detail.

FIG. 3 is a view illustrating an electric field distribution status of a TE114 mode used in a bandpass filter of FIG. 1.

FIG. 4 is a view illustrating an electric field distribution status of a TE011 mode used in the bandpass filter of FIG. 1.

FIGS. 5A and 5B show a perspective view and a cross-sectional view illustrating a common pole structure in which a plurality of bandpass filters of FIG. 1 are coupled to a coupler in detail.

FIG. 6 is a schematic configuration diagram illustrating an artificial intelligence learning model for performing tuning of the bandpass filter of FIG. 1 in detail.

### DETAILED DESCRIPTION OF EXEMPLARY EMBODIMENTS

Specific embodiments of the present invention will be described with reference to the accompanying drawings.

The present invention can be modified in various forms and can have various embodiments. Specific embodiments will be shown in the accompanying drawings and described in detail. However, it is to be understood that the present invention is not limited to the specific embodiments but includes all modifications, equivalents, and substitutions included in the spirit and the scope of the present invention.

Hereinafter, a radio frequency (RF) multiplexer of a 5G mmWave low-loss broadband wireless hybrid type using a waveguide cavity Ka-band will be described with reference to the accompanying drawings.

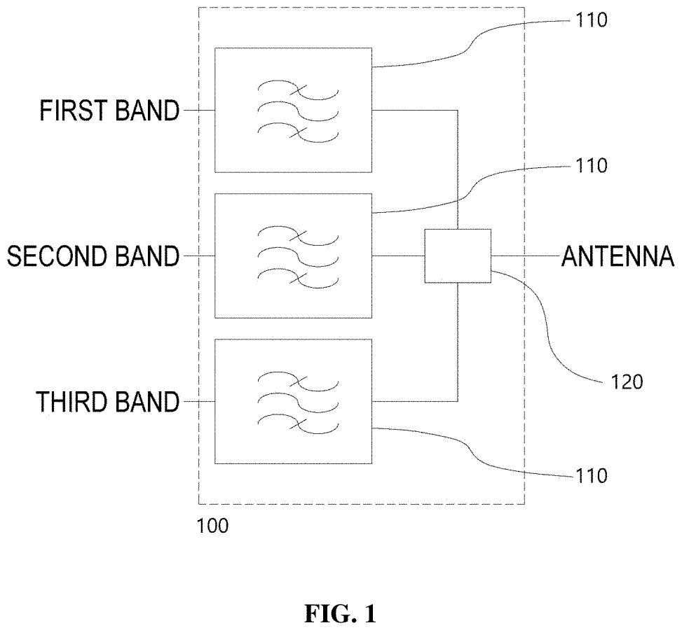

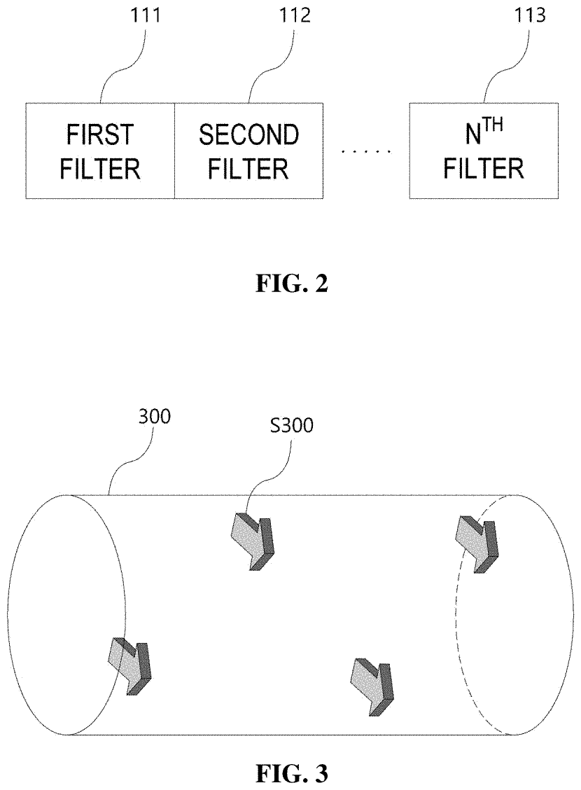

FIG. 1 is a configuration diagram illustrating an RF multiplexer of a 5G mmWave low-loss broadband wireless hybrid type using a waveguide cavity Ka-band according to one embodiment of the present invention. FIGS. 2 to 6 are a detailed block diagram, views, a cross-sectional view, and a schematic configuration diagram for describing FIG. 1 in detail.

Hereinafter, the RF multiplexer of the 5G mmWave low-loss broadband wireless hybrid type using the waveguide cavity Ka-band according to one embodiment of the present invention will be described in detail with reference to FIGS. 1 to 6.

First, referring to FIG. 1, the RF multiplexer of the 5G mmWave low-loss broadband wireless hybrid type using the waveguide cavity Ka-band according to one embodiment of the present invention includes bandpass filters 110 which may receive signals in an RF frequency band to perform tuning and a coupler 120 which combines outputs of at least two bandpass filters 110 to match an antenna.

Here, the RF frequency band is a satellite frequency band, and a first band of 26.5 GHz to 27.3 GHz, a second band of 27.3 GHz to 28.1 GHz, and a third band of 28.1 GHz to 28.9 GHz are used.

A 5G mobile communication band of 28 GHz is defined as 26.5 GHz to 27.3 GHz by KT, 27.3 GHz to 28.1 GHz by LGU+, and 28.1 GHz to 28.9 GHz by SKT. Because a satellite should be heavy in order to perform filtering on signals in such bands to use corresponding antennas, it is necessary to share an antenna.

Here, while a weight of a satellite is reduced as compared with an existing RF multiplexer 100, the performance thereof should be increased, and in particular, there is a requirement that passive inter-modulation distortion (PIMD) performance should be excellent for high-power transmission.

According to the present invention, there may be provided an RF multiplexer 100 having a size and improved performance to satisfy the requirement.

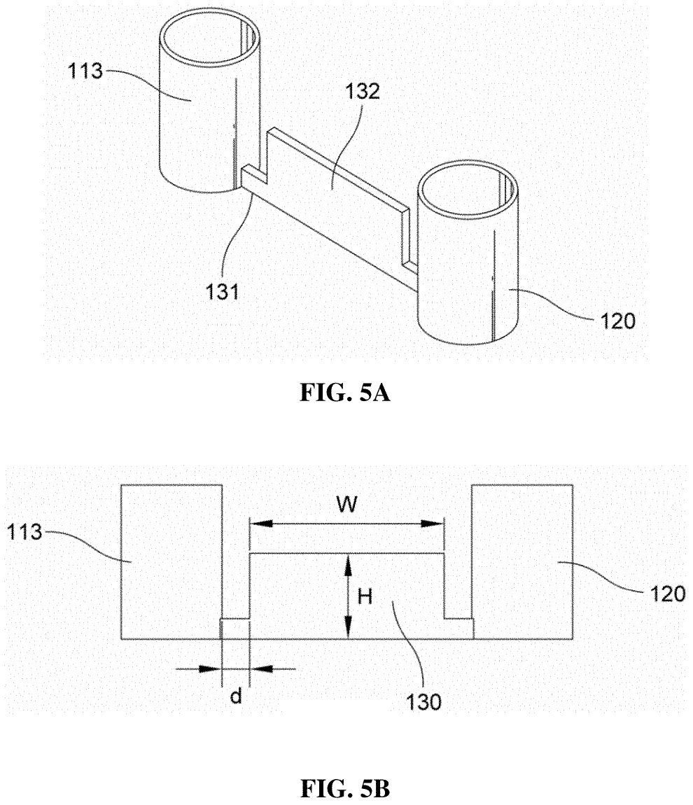

In the bandpass filter 110 of the present invention, a TE114 mode and a TE011 mode may be coupled in series to reduce the size and weight of the RF multiplexer 100, which will be described in detail below with reference to FIGS. 2 to 4. In addition, the coupler 120 may perform common pole combining to improve the characteristics of PIMD and increase insertion loss performance, which will be described in FIGS. 5A and 5B.

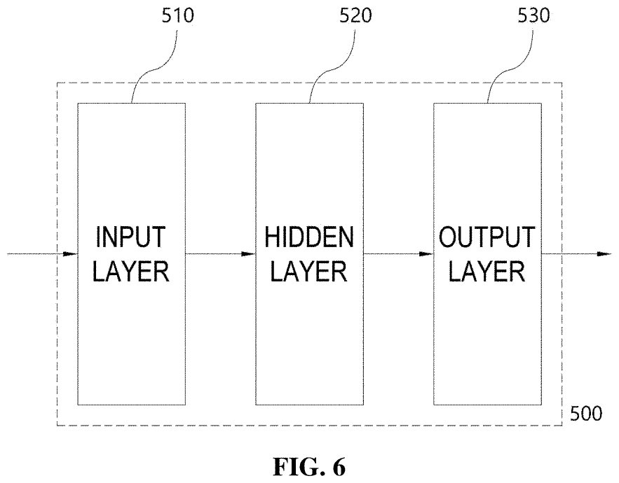

Meanwhile, the bandpass filter 110 should perform tuning according to an input band. In the present invention, machine learning may be introduced to increase tuning accuracy, which will be described in detail in FIG. 6.

FIG. 2 is a block diagram illustrating the RF multiplexer 100 of FIG. 1 in detail.

As can be seen in FIG. 2, the bandpass filter 110 may be formed by consecutively coupling resonators in one mode or at least two different modes.

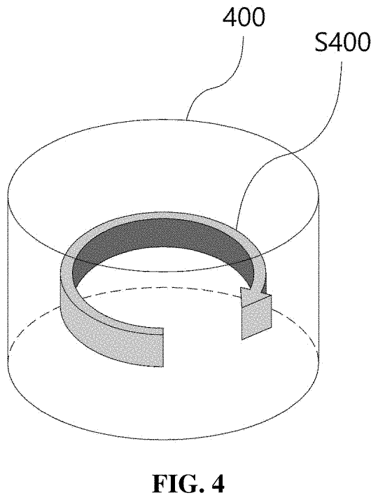

Here, a first filter 111 and second to N^{th} filters 112 to 113 may be used in one mode or may be coupled using at least two different modes, which will be described in detail with reference to FIGS. 3 and 4.

FIG. 3 is a view illustrating an electric field distribution status of a TE114 mode used in the bandpass filter 110 of FIG. 1, and as can be seen in FIG. 3, the TE114 mode is used.

The bandpass filter 110 constituting TE114 may include a TE114 filter housing 300 and a TE114 filter internal electric field S300 that has an electric field distribution inside the TE114 filter housing 300.

Here, the first filter 111 and the second to N^{th} filters 112 to 113 constituting the bandpass filter 110 can minimize an insertion loss by improving flatness of a frequency band to be filtered. To this end, the bandpass filter 110 is formed according to an appropriate order, and it is necessary to reject signals present outside the frequency band.

As the order of the bandpass filter 110 becomes higher, a bandwidth may become wider, sharp rejection may be obtained, and a group delay may be small. However, since a size is increased to increase a weight as an order of a channel filter becomes higher, the bandpass filter 110 should be formed according to an appropriate order.

Meanwhile, since the size and weight of parts used for a mobile communication satellite are very important factors, there is a need for a method of minimizing the weight while maintaining performance required for the corresponding satellite. In order to satisfy such requirements, conventionally, the bandpass filter 110 has been generally formed using a cylindrical cavity that generates a mode. In this case, in the bandpass filter 110, a mode is implemented as a dual mode to allow two resonances to occur in one cavity, thereby minimizing the size of the bandpass filter 110.

When a TE11m mode is used, an insertion loss at a center of a passband corresponding to the bandpass filter 110 may be determined to a certain extent. Here, when m is increased in the TE11m mode, an insertion loss at an edge of a passband for filtering through a channel filter is reduced. In this case, flatness of the passband is improved, thereby minimizing the insertion loss in the passband.

However, since the length of the bandpass filter 110 increases as m is increased in a mode, there is a disadvantage in that a weight, a volume, and an area occupied by the bandpass filter 110 in a panel of a satellite payload increase. When m is greater than or equal to 5 in a mode, an advantage in terms of insertion loss considerably decreases, but a length considerably increases. Accordingly, in the bandpass filter 110, m is made to be approximately 4 in a mode, thereby finding a balance point between an insertion loss and a size/weight.

Next, FIG. 4 is a view illustrating an electric field distribution status of a TE011 mode used in the bandpass filter 110 of FIG. 1, and as can be seen in FIG. 4, the TE011 mode is used.

As described with reference to FIG. 3, in order to reduce the size and weight of the bandpass filter 110, the bandpass filter 110 may use a TE112 mode or a TE113 mode, but in this case, a quality factor may be decreased to increase an insertion loss in a passband. In addition, an insertion loss at an edge of the passband may further increase, thereby degrading electrical performance.

However, the TE11m mode does not have a very high quality factor among resonance modes using a cylindrical cavity. Among the TE01m modes, the TE011 mode has the highest quality factor among resonance modes that are actually used.

Therefore, the present invention provides a method of reducing the length of the bandpass filter 110 by replacing a cylindrical cavity for generating a TE114 mode with a cylindrical cavity for generating a TE011 single mode using such characteristics. As described above, when the bandpass filter 110 of the present invention having the reduced length is used, it is possible to reduce the size and weight of other elements for fixing the bandpass filter 110.

Meanwhile, in TE011, it can be seen that the bandpass filter 110 includes a TE011 filter internal electric field S400 that has an electric field distribution inside a TE011 filter housing 400. Therefore, in the present invention, the TE114 of FIG. 3 and the TE011 of FIG. 4 may be combined at a right angle according to an electric field distribution.

FIG. 5 and FIG. 6 show a perspective view and a cross-sectional view illustrating a common pole structure in which the plurality of bandpass filters 110 of FIG. 1 are coupled to the coupler 120 in detail.

As can be seen in FIGS. 5A and 5B, the coupler 120 connects outputs of at least two bandpass filters 110 through a signal connection wall 130 to combine the outputs to a common pole. In addition, the signal connection wall 130 includes a base 131 which connects the bandpass filter 110 and the coupler 120 and an upper extension portion 132 positioned on an upper end of the base 131.

As can be seen in FIGS. 5A and 5B, in common pole combining of the present invention, frequency band signals may be introduced into the bandpass filter 110, and the plurality of frequency band signals may be combined by the coupler 120 in the signal connection wall 130 to be output to an antenna.

Here, the N^{th} filter 113, which is a last output filter in the bandpass filter 110, is provided to be connected to the coupler 120, and the signal connection wall 130 is provided to connect the N^{th} filter 113 to the coupler 120. In addition, the signal connection wall 130 may include the base 131 which connects the N^{th} filter 113 and the coupler 120 and the upper extension portion 132 which extends upward from the base 131 and is formed apart from each of the N^{th} filter 113 and the coupler.

That is, as shown in FIG. 5A, one side of the signal connection wall 130 is connected to the coupler 120 through the base 131 formed at a lower side of the signal connection wall 130, and the other side thereof is connected to the N^{th} filter 113 by extending to an inner side of a terminal cavity that constitutes each of channel filters.

As shown in FIG. 5B, the signal connection wall 130 having such a configuration may perform impedance matching on a frequency band signal based on a height H, a width W, and a separation distance d of the upper extension portion 132. Therefore, by adjusting the height H, the width W, and the separation distance d of the upper extension portion 132, proper impedance matching may be performed for a transmission/reception frequency band.

Therefore, according to the present invention, since signals in various frequency bands passing through the plurality of bandpass filters 110 are impedance-matched by the signal connection wall 130 and then are input to the coupler 120, a high output signal can be transmitted through one antenna. In addition, a signal received through the antenna can also be output to a connection port through the bandpass filters 110.

In addition, since a portion of the signal connection wall 130 having a radial shape extends and is accommodated inside the terminal cavity, the coupler 120 has excellent space utilization and can be integrally molded during injection molding.

As described above, according to the present invention, signals input to the coupler 120 through the bandpass filters 110 are combined and transmitted through one antenna. In addition, a signal received through the antenna is input to each of the bandpass filters 110 through the coupler 120, thereby providing a structure capable of performing bidirectional transmission and reception.

Meanwhile, in order to minimize a loss of a signal transmitted to the coupler 120 through each of the bandpass filters 110 or received by an antenna and input to each of the bandpass filters 110 through the coupler 120, in the present invention, outer surfaces of the coupler 120 and the signal connection wall 130 may be plated with a conductive material.

As such plating, plating of silver having excellent conductivity may be performed, and a thickness of the plating of silver may be a thickness of 6 μm to 15 μm.

FIG. 6 is a schematic configuration diagram illustrating an artificial intelligence learning model for performing tuning of the bandpass filter 110 of FIG. 1 in detail.

As can be seen in FIG. 6, tuning in the present invention is performed based on a result of performing machine learning using an artificial intelligence learning model 500 based on an input/output value and a tuning depth of the RF multiplexer 100 including the plurality of bandpass filters 110 and one coupler 120.

In addition, the artificial intelligence learning model 500 includes an input layer 510, a hidden layer 520, and an output layer 530. The input/output value and the tuning depth of the RF multiplexer 100 are input to the input layer 510, and tuning depth control is performed through the output layer 530 to satisfy a target characteristic.

Here, the target characteristic may be set to at least one of an insertion loss for each frequency, a reflective loss, and isolation between inputs.

In addition, the machine learning may be performed by updating a reward function of Monte-Carlo learning (MCL) based on a condition that satisfies the above target characteristic.

Here, in the machine learning, for the tuning depth control for satisfying the target characteristic, temporal difference learning (TDL) for updating a reward function immediately for each time step is performed. Meanwhile, when the target characteristic is satisfied, the MCL for updating a reward function for all states is performed based on the target characteristic.

As shown in FIG. 6, the artificial intelligence learning model 500 of the present invention includes the input layer 510 which receives the input/output value and the tuning depth of the RF multiplexer 100, the output layer 530 which controls the tuning depth, and the hidden layer 520 which includes a deep neural network connected between the input layer 510 and the output layer 530 to form a connection relationship between the input layer 510 and the output layer 530.

Here, the artificial intelligence learning model 500 updates the reward function of the MCL based on a case in which the target characteristic is satisfied. In this case, for artificial intelligence learning, the artificial intelligence learning model 500 may simultaneously perform the MCL and the TDL.

The MCL and the TDL are based on a Markov decision process, are methods of sequentially updating a value function based on information actually experienced in a manner of trial and error, and are types of reinforcement learning of the present invention for estimating a value of a reward function by averaging a sampling without considering a total number of cases.

The MCL updates a reward function for all states experienced during an episode after the episode ends, but the TDL has an advantage that it is capable of updating a reward function for each time step immediately without needing to wait until an episode ends.

Therefore, in the present invention, in the tuning depth control for satisfying the target characteristic, the TDL may be performed, and when the target characteristic is satisfied, a reward function may be updated by differentiating a compensation value based on the target characteristic.

As described above, in the present invention, there is an advantage in that accurate and fast filter tuning can be performed by introducing machine learning to tuning depth control.

In the above-described RF multiplexer of the 5G mmWave low-loss broadband wireless hybrid type using the waveguide cavity Ka-band according to the present invention, outputs of a mobile communication band communication system using a plurality of satellite frequencies are combined, thereby reducing an insertion loss and increasing PIMD performance, and signals at adjacent frequencies in a 5G mobile communication band are effectively filtered using a single mode or multiple modes, thereby reducing a size of a filter to reduce a weight thereof.

The above-described embodiments include real examples of one or more embodiments. Of course, although not all possible combinations of the components or the methods for describing the above-described embodiments can be described, those skilled in the art may recognize additional combinations and replacements of the various embodiments. Therefore, the above-described embodiments include all alternatives, modifications, and changes within the spirit and the scope of the appended claims.

What is claimed is:

1. A radio frequency (RF) multiplexer of a 5G mmWave low-loss broadband wireless hybrid type using a waveguide cavity Ka-band, comprising:
band-pass filters which receive signals in an RF frequency band to perform tuning; and
a coupler which combines outputs of at least two bandpass filters to match an antenna.

2. The RF multiplexer of claim 1, wherein, the RF frequency band is a satellite bane and uses a first band of 26.5 GHz to 27.3 GHz, a second band of 27.3 GHz to 28.1 GHz, and a third band of 28.1 GHz to 28.9 GHz.

3. The RF multiplexer of claim 1, wherein the bandpass filter is formed by consecutively coupling resonators in one mode or at least two different modes.

4. The RF multiplexer of claim 3, wherein the mode uses a TE114 mode.

5. The RF multiplexer of claim 3, wherein the mode uses a TE011 mode.

6. The RF multiplexer of claim 1, wherein the coupler combines the outputs of the at least two bandpass filters through a signal connection wall to couple the outputs to a common pole.

7. The RF multiplexer of claim 6, wherein the signal connection wall includes:
a base configured to connect the bandpass filter and the coupler; and
an upper extension portion positioned on an upper end of the base.

8. The RF multiplexer of claim 1, wherein the tuning is performed based on a result of performing machine learning using an artificial intelligence learning model based on an input/output value and a tuning depth of the RF multiplexer including the plurality of bandpass filters and one coupler.

9. The RF multiplexer of claim 8, wherein:
the artificial intelligence learning model includes an input layer, a hidden layer, and an output layer; and
the input/output value and the tuning depth of the RF multiplexer are input to the input layer, and tuning depth control is performed through the output layer to satisfy a target characteristic.

10. The RF multiplexer of claim 9, wherein the target characteristic is at least one of an insertion loss for each frequency, a reflective loss, and isolation between inputs.

11. The RF multiplexer of claim 9, wherein, in the machine learning, a reward function of Monte-Carlo learning is updated based on a condition that satisfies the target characteristic.

12. The RF multiplexer of claim 9, wherein, in the machine learning, for the tuning depth control for satisfying the target characteristic, temporal difference learning for updating a reward function immediately for each time step is performed, and when the target characteristic is satisfied, Monte-Carlo learning for updating a reward function for all states is performed based on the target characteristic.
